(19) United States
(12) Patent Application Publication
(10) Pub. No.: US 2009/0250724 A1
(43) Pub. Date: Oct. 8, 2009

(54) BIPOLAR TRANSISTOR AND METHOD OF MAKING SUCH A TRANSISTOR

(75) Inventor: John Nigel Ellis, Devon (GB)

Correspondence Address: THOMPSON HINE L.L.P.;Intellectual Property Group, P.O. BOX 8801, DAYTON, OH, 45401-8801, US

(73) Assignee: X-FAB SEMICONDUCTOR FOUNDRIES AG, Erfurt (DE)

(21) Appl. No.: 11/721,717

(22) PCT Filed: Dec. 14, 2005
(86) PCT No.: PCT/GB2005/050250

§ 371 Date: Nov. 16, 2007

(30) Foreign Application Priority Data
Dec. 15, 2004 (GB) 0427363.7

(51) Int. Cl. H01L 29/73; H01L 21/331

(52) U.S. Cl. 257/197; 438/341; 257/616; 257/587; 438/350; 257/E29.174; 257/E21.372

(57) ABSTRACT

A bipolar transistor is formed on a heavily doped silicon substrate (1). An epitaxially grown collector (12) is formed on the substrate (1) and comprises silicon containing germanium at least at the top of the collector (12). An epitaxial base (13) is formed on the collector (12) to have the opposite polarity and also comprises silicon containing germanium at least at the bottom of the base (13). An emitter is formed at the top of the base (13) and comprises polysilicon doped to have the same polarity as the collector (12).

The present invention relates to a bipolar transistor and to a method of making such a transistor. Such techniques may be applied to bipolar power transistors, for example for high performance linear or switching applications. Examples of applications for such transistors include audio amplifiers, switching power supplies and linear radio frequency amplifiers.

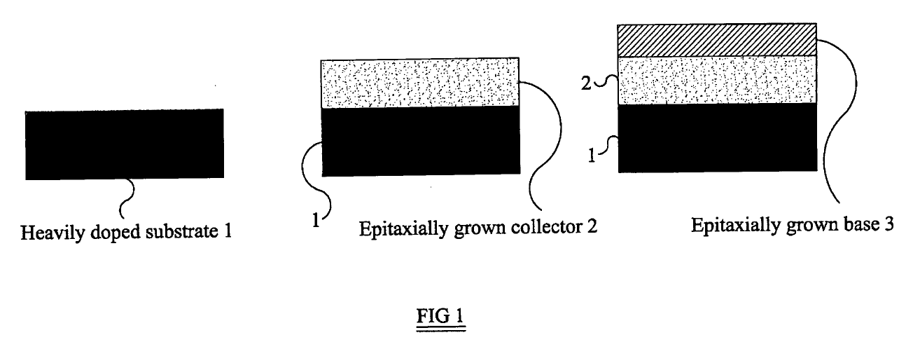

FIG. 1 of the accompanying drawings illustrates diagrammatically part of a known process of making a bipolar power transistor. The transistor is made on a heavily doped substrate 1 of n-type for an NPN transistor or of p-type for a PNP transistor. One or more epitaxial layers may be grown on the substrate. Typically one layer would be used for an epitaxial-base type while additional layers may be used to form a lightly doped collector region 2 before forming the base 3. A plurality of epitaxial layers are grown on the substrate 1 to form a lightly doped collector 2. An epitaxial layer is then grown on the collector to form a medium doped base 3.

Various techniques are subsequently used in order to form an emitter. In one technique, a layer of the appropriate polarity is diffused or implanted and a masking and photolithographic process is used to etch away parts of the resulting layer to leave the emitter. In another known technique, an oxide layer is grown on the base and regions which are to be implanted so as to become the emitter are masked and etched. A second mask is then used to open regions for forming a base contact diffusion. A diffusion step is then performed to drive the emitter and base contact diffusions to the right depths and to tailor the collector and base profiles so as to improve second breakdown performance.

U.S. Pat. No. 6,660,623 discloses a technique of this type in which the base additionally contains germanium. In this known technique, the concentration of germanium decreases so as to be zero or close to zero at the top of the base to allow the emitter region to be formed conventionally of silicon. Such grading relieves stress in the base caused by the different lattice sizes of silicon and germanium but limits the base width and the maximum achievable germanium concentration in the base.

Transistors of this type including germanium in the base have advantages in that it is possible to provide high current gains in power devices. For example, current gains of five hundred may be achievable at collector currents of the order of four amps. Thus, such devices may be used in place of Darlington transistors and provide advantages such as low drive requirement, a single input diode, and good high frequency roll-off characteristics. However, as mentioned above, because a germanium crystal lattice is larger than a silicon crystal lattice, the presence of germanium in the base can generate a strain in the crystal. Such a strain can create stress lines which result in higher device leakage and lower current gains than would otherwise be expected.

U.S. Pat. No. 5,440,152 discloses a “heterojunction” bipolar transistor of silicon type comprising first and second collector regions containing germanium, a base region containing germanium, and an emitter region made of single crystal silicon which may contain germanium. The concentration of germanium in the base region increases with depth towards the adjacent first collector region. The concentration of germanium in the first and second collector regions decreases with depth at first and second rates, respectively, where the second rate is smaller than the first rate.

According to a first aspect of the invention, there is provided a bipolar transistor comprising: a silicon substrate of a first polarity; an epitaxial collector formed on the substrate and comprising silicon doped to have the first polarity, at least a portion at or adjacent the top of the collector containing germanium; an epitaxial base formed on the collector and comprising silicon doped to have a second polarity opposite the first polarity, at least a portion at or adjacent the bottom of the base containing germanium; and an emitter formed at the top of the base and comprising silicon doped to have the first polarity, characterised in that the emitter comprises polysilicon.

The transistor may comprise a power transistor.

The substrate may comprise silicon doped to a higher concentration than at least the top of the collector to have the first polarity. The concentration of dopant in the collector may reduce with distance from the substrate. The concentration of dopant at the bottom of the collector may be substantially to equal to that of the substrate.

The collector may have a substantially constant concentration of X % by weight of germanium, where 0<X<100. As an alternative, the concentration by weight of germanium in the collector may vary from substantially 0% at the bottom of the collector to X % at the top of the collector, where 0<X<100.

The concentration of germanium at the top of the collector may be substantially equal to the concentration of germanium at the bottom of the base.

The base may have a substantially constant concentration of germanium. As an alternative, the concentration of germanium in the base may decrease substantially monotonically from the bottom of the base to the top of the base. The concentration of germanium at the top of the base may be substantially 0%.

According to a second aspect of the invention, there is provided a method of making a bipolar transistor, comprising the steps of:
forming on a silicon substrate of a first polarity an epitaxial collector comprising silicon doped to have the first polarity, at least a portion at or adjacent the top of the collector containing germanium;
forming on the collector an epitaxial base comprising silicon doped to have a second polarity opposite the first polarity, at least a portion at or adjacent the bottom of the base containing germanium; and
forming at the top of the base an emitter comprising polysilicon doped to have the first polarity.

It is thus possible to provide a bipolar transistor in which the problems associated with strain in the crystal can be substantially reduced or eliminated. For example, it is possible to grow a silicon epitaxial base layer with a very high concentration of germanium on top of a collector layer so as to avoid or minimise crystal defects. A substantially higher concentration of germanium can be achieved than is possible with known techniques where there is no grading of germanium in the collector and the emitter is single-crystal silicon. Power transistors of improved performance as compared with known devices. Also, doping levels and profiles can be varied so that the resulting transistor parameters can be selected for improved performance in a variety of different applications.

The invention will be further described, by way of example, with reference to the accompanying drawings, in which:

FIG. 1 is a diagram illustrating a known bipolar power transistor manufacturing process;

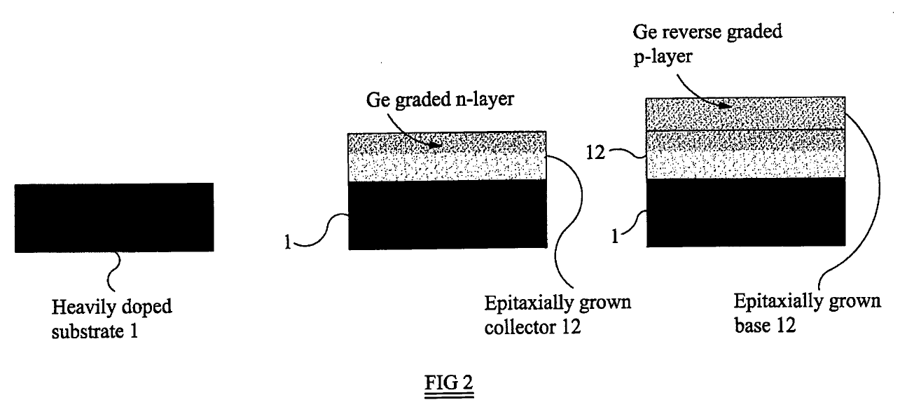

FIG. 2 is a diagram illustrating a method constituting an embodiment of the invention for producing a bipolar power transistor also constituting an embodiment of the invention; and

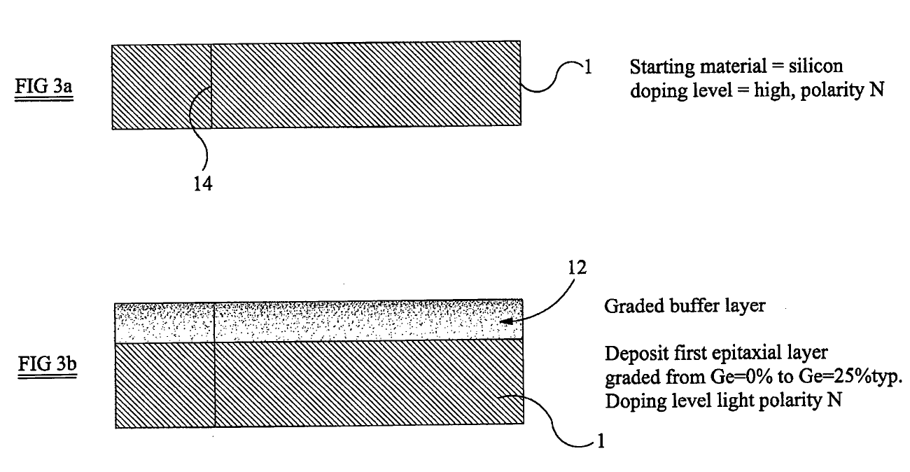

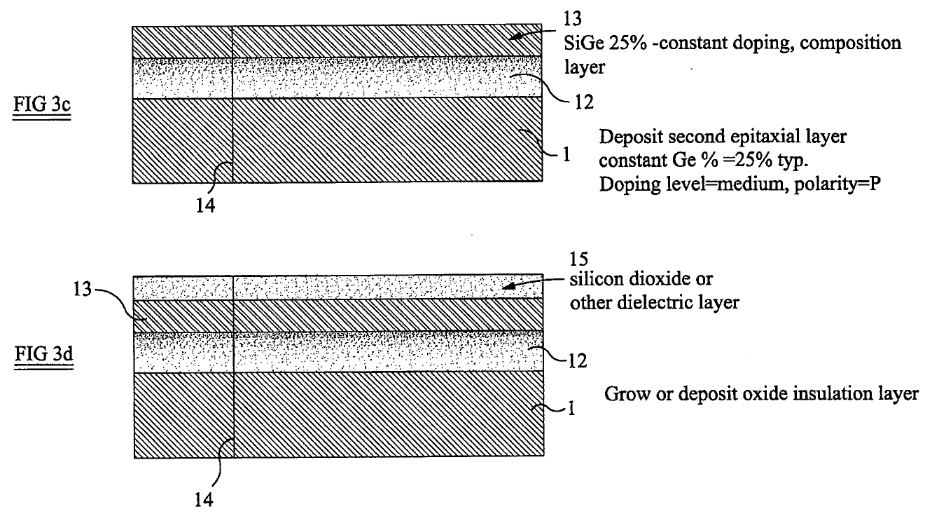

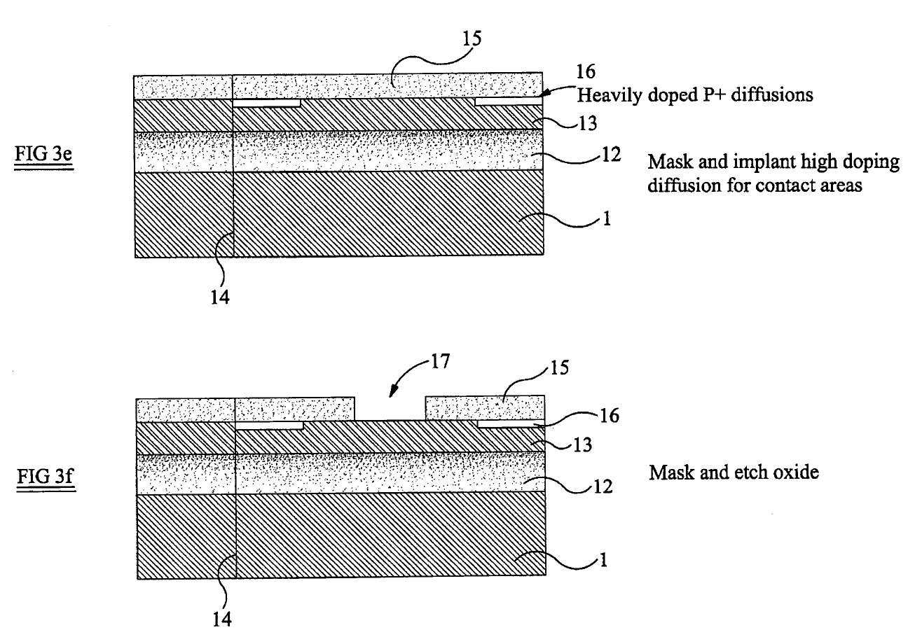

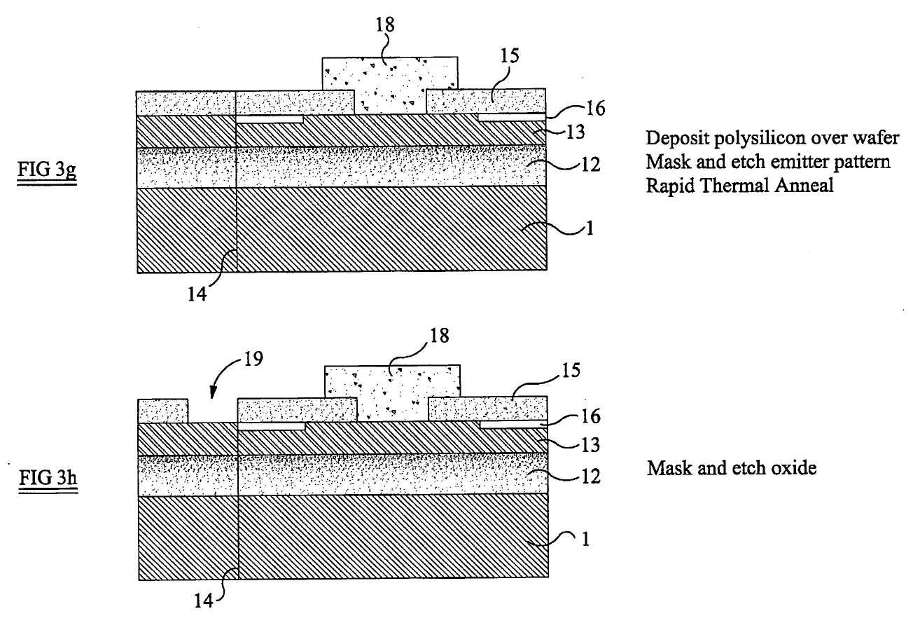

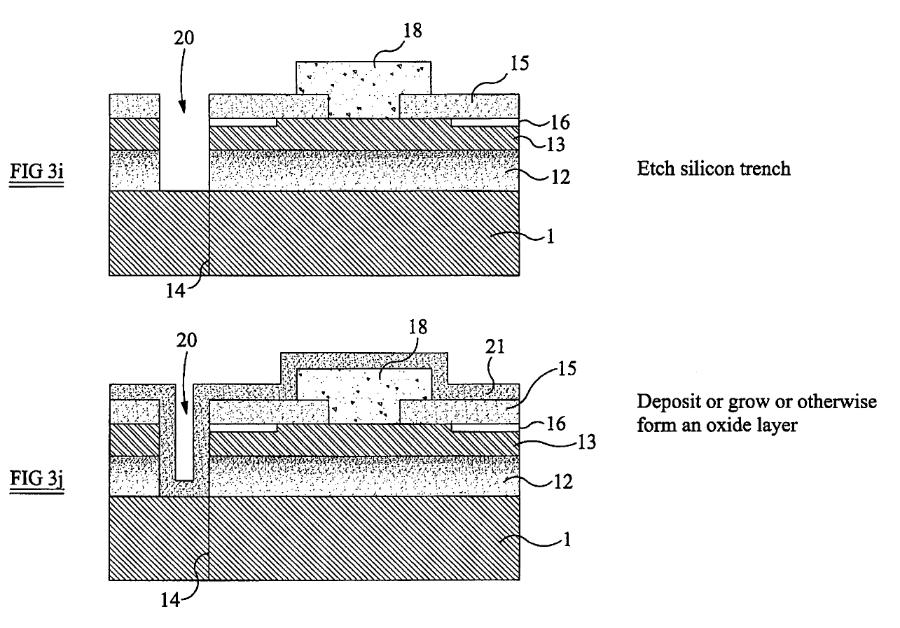

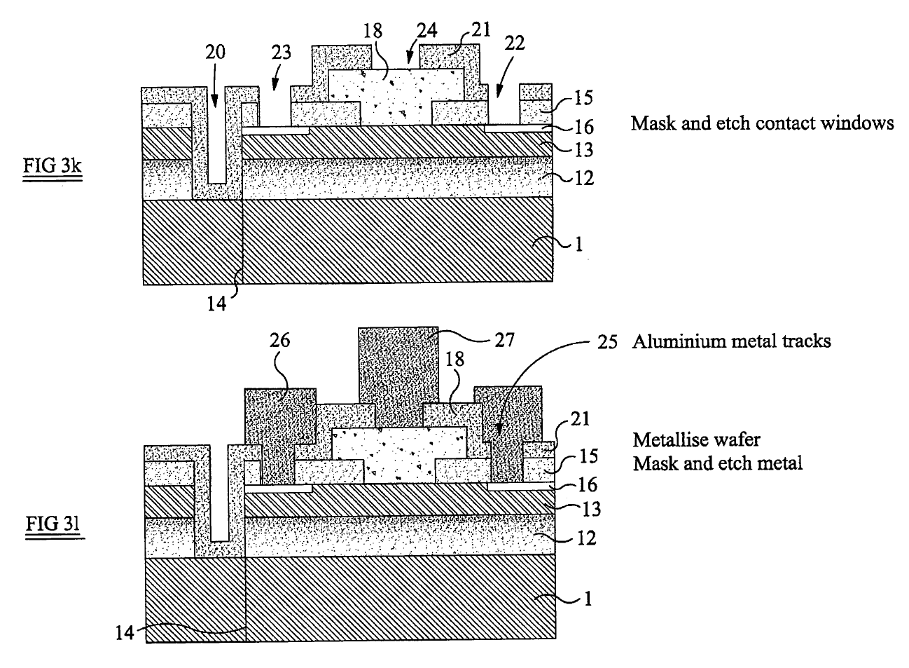

FIGS. 3a to 3l is a more detailed diagram illustrating an example of a method constituting an embodiment of the invention.

FIG. 2 illustrates an example of a method of making an NPN bipolar power transistor. PNP bipolar power transistors may also be made by such a method, for example by using opposite doping polarities. As in FIG. 1, the method starts from the formation of a heavily doped n-type silicon substrate 1. A collector 12 is epitaxially grown on the substrate 1 and contains a light doping of the same polarity (n-type) as the substrate 1. The collector 12 may be grown as a single layer or as sequentially grown layers and is formed to within 10 microns of its target thickness. For example, for a 100 volt-rated transistor, the total thickness of the collector 12 may be 10 microns.

In addition to the n-type dopant used to form the collector 12, the layer or a part of the layer forming the collector contains germanium whose concentration is graded, for example so as to be substantially zero at the bottom of the collector 12 and X % by weight at the top of the collector, where 0<x<100. For example, the concentration by weight of germanium at the top of the collector 12 may be substantially equal to 15% for a typical bipolar transistor of this type. However, the germanium concentration and profile may be adjusted or varied in order to suit different applications of the resulting bipolar power transistor.

A base 13 is epitaxially grown on the top of the collector 2. The base is formed of silicon with a p-type dopant and with a relatively high percentage by weight of germanium. In particular, the base band-gap is narrower substantially in proportion to the germanium concentration. In the case of 15% by weight of germanium, a 60 mV reduction in band-gap may be achieved. This allows the current gain of the resulting transistor to be increased by a factor of the order of 10 for a given base doping. Alternatively, the germanium in the base 13 may be used to increase the base doping level and to increase the Early voltage, reduce the base resistance, and reduce the base width for higher switching speeds. The base may be more heavily doped than in the case of conventional silicon bipolar transistors which do not contain germanium.

In practice, improvements to the current gain, Early voltage, base resistance and base thickness may be varied or selected so as to provide power transistors adapted to specific requirements or applications.

During deposition of the base 13, the germanium concentration is reduced to zero or close to zero at the top of the base 13. An emitter region may therefore be formed of n-doped silicon but without germanium. Grading of the germanium concentrations in the collector 1 and the base 13 relieves stress in the layers.

In order to form the emitter, another layer of n-type silicon is deposited on top of the base. The emitter is formed of polycrystalline silicon (polysilicon) grown with in-situ doping, so that the whole of the base 12 may contain a relatively high percentage of germanium throughout the whole layer. A short rapid thermal process may be used to complete the transistor structure. This process step minimises stress formation from lattice mismatch, which would be generated by a conventional emitter diffusion into a silicon layer.

Various modifications are possible. For example, as described above, the concentration of germanium in the base 13 may be graded or may be substantially constant. Also, the n-type dopant in the collector 12 may vary or may be substantially constant. The concentration may, for example, be graded from being substantially equal to the substrate concentration at the bottom of the collector to a low concentration at the top of the collector. In the case of constant or uniform concentration, the concentration may be same as or lower than that of the substrate 1. The n-type dopant and germanium concentrations and/or grading may therefore, for example, be optimised for switching applications or linear applications of the resulting transistor.

Also, as mentioned above, the germanium concentration in the base 13 may be substantially constant throughout the base or may be graded to zero.

FIGS. 3a to 3l illustrate in more detail a particular example of a method of making an NPN bipolar power transistor. A PNP transistor may be made by the same method but with opposite polarity dopants and layers. The starting material is a substrate 1 comprising highly doped N-type silicon forming part of a silicon wafer (FIG. 3a). Several devices may be made on the same wafer and the left end of the transistor is illustrated at 14.

In a first step (FIG. 3b), a graded buffer layer which will form the collector 12 of the transistor is deposited on the substrate 1 by epitaxial growth. The collector 12 is of lightly doped N-type silicon containing germanium with a graded concentration. In particular, in this example, the concentration by weight of germanium is 0% at the bottom of the collector (adjacent the substrate 1) and increases monotonically to, for example, 25% at the top of the collector 12.

A second epitaxial layer for forming the base 13 of the transistor is deposited on top of the collector 12 (FIG. 3c) and comprises silicon of medium doping level of P-type together with germanium. The concentration of germanium is substantially constant throughout the thickness of the base and is substantially equal to 25%, i.e. substantially the same as the germanium concentration at the top of the collector 12. A silicon dioxide or other dielectric layer 15 is then grown or deposited on top of the base 13 as shown in FIG. 3d.

The upper surface is then masked and heavily doped P+ diffusions such as 16 are formed for providing contact areas (FIG. 3e). The masking is removed and a further masking is provided and etched to reveal a window 17 for the formation of an emitter (FIG. 3f).

A polysilicon region of N-type is deposited on the top surface of the wafer and then etched to provide an emitter 18 as shown in FIG. 3g. This is followed by a rapid thermal annealing process to establish the emitter/base junction of the transistor. The upper surface of the substrate is then again masked and the oxide layer 15 is etched to form an opening 19 (FIG. 3h). The silicon underlying the opening 19 is then etched to form a wafer 20 as shown in FIG. 3i for effectively isolating the transistor from the rest of the wafer.

A further oxide layer 21 is deposited or grown on the upper surface of the wafer (FIG. 3j) and is masked and etched to reveal base contact windows 22 and 23 and an emitter contact window 24 (FIG. 3k). The upper surface of the wafer is then metalised, masked and etched to provide metal contacts, such as aluminium tracks 25 and 26, for the base 13 and an aluminium track 27 for the emitter 18 (FIG. 31). This completes the formation of the transistor structure, which may then be processed in any suitable way, for example, for separating and encapsulating the device.

It is thus possible to provide a range of transistors with base widths from less than 1 micron to more than 10 microns in order to provide a range of operating collector voltages and characteristics. For example, in the case of a base with a graded or varying concentration of germanium, it is possible to provide a transistor with a highly linear collector current-to-gain characteristic by using a higher base doping concentration to generate a high internal voltage, thereby creating a potentially high current injection capability before high level injection effects impact on the characteristics. However, the structural parameters of the transistor may be selected in order to achieve a desirable combination of performance parameters. For example, a relatively wide base may be used in order to achieve a high current gain. Conversely, a relatively narrow base with a higher concentration of doping may be used to increase the Early voltage and the high current roll-off point, thus increasing the gain linearity over a wide range of collector currents. Reducing the base width may be used to increase the frequency response of the transistor. Also, the base voltage distribution within the transistor may be improved.

1. A bipolar transistor comprising: a silicon substrate of a first polarity; an epitaxial collector formed on the substrate and comprising silicon doped to have the first polarity, at least a portion at or adjacent the top of the collector containing germanium; an epitaxial base formed on the collector and comprising silicon doped to have a second polarity opposite the first polarity, at least a portion at or adjacent the bottom of the base containing germanium; and an emitter formed at the top of the base and comprising silicon doped to have the first polarity, characterised in that the emitter is formed of polysilicon.

2. A transistor as claimed in claim 1, wherein the transistor is a power transistor.

3. A transistor as claimed in claim 1, wherein the substrate comprises silicon doped to a higher concentration than at least the top of the collector to have the first polarity.

4. A transistor as claimed in claim 3, the concentration of dopant in the collector reduces with distance from the substrate.

5. A transistor as claimed in claim 4, wherein the concentration of dopant at the bottom of the collector is substantially equal to that of the substrate.

6. A transistor as claimed in claim 1, wherein the collector has a substantially constant concentration of X % by weight of germanium, where 0<X<100.

7. A transistor as claimed in claim 1, wherein the concentration by weight of germanium in the collector varies from substantially 0% at the bottom of the collector to X % at the top of the collector, where 0<X<100.

8. A transistor as claimed in claim 1, wherein the concentration of germanium at the top of the collector is substantially equal to the concentration of germanium at the bottom of the base.

9. A transistor as claimed in claim 1, wherein the base has a substantially constant concentration of germanium.

10. A transistor as claimed in claim 1, wherein the concentration of germanium in the base decreases substantially monotonically from the bottom of the base to the top of the base.

11. A transistor as claimed in claim 1, wherein the concentration of germanium at the top of the base is substantially 0%.

12. A method of making a bipolar transistor, comprising the steps of:
forming on a silicon substrate of a first polarity an epitaxial collector comprising silicon doped to have the first polarity, at least a portion at or adjacent the top of the collector containing germanium;
forming on the collector an epitaxial base comprising silicon doped to have a second polarity opposite the first polarity, at least a portion at or adjacent the bottom of the base containing germanium; and
forming at the top of the base an emitter comprising polysilicon doped to have the first polarity.

13. A transistor as claimed in claim 1, wherein the polysilicon is deposited on top of the base so as to form the emitter.
